(19) United States
(12) Patent Application Publication
(10) Pub. No.: US 2020/0340757 A1
(43) Pub. Date: Oct. 29, 2020

(54) EXPANDED GRAPHITE-ENHANCED VAPOR-BASED HEAT TRANSFER DEVICE AND PRODUCTION PROCESS

(71) Applicant: Nanotek Instruments, Inc., Dayton, OH (US)

(72) Inventors: Yi-jun Lin, Taoyuan City (TW); Bor Z. Jang, Centerville, OH (US)

(73) Assignee: Nanotek Instruments, Inc., Dayton, OH (US)

(21) Appl. No.: 16/397,284

(22) Filed: Apr. 29, 2019

(51) Int. Cl. F28D 15/04; H05K 7/20; H01L 31/052; H01L 23/427; F28D 15/02

(52) U.S. Cl. CPC F28D 15/046; H05K 7/20336; H05K 7/20309; H05K 7/20318; F28D 15/043; H01L 31/0521; H01L 23/427; F28D 15/0283; H05K 7/2039

(57) ABSTRACT

Provided is a vapor-based heat transfer apparatus (e.g. a vapor chamber or a heat pipe), comprising: a hollow structure having a hollow chamber enclosed inside a sealed envelope or container made of a thermally conductive material, a wick structure in contact with one or a plurality of walls of the hollow structure (interior wall of the hollow chamber), and a working liquid within the hollow chamber and in contact with the wick structure, wherein the wick structure comprises flakes of exfoliated graphite worms or expanded graphite. Preferably, these flakes are substantially parallel to one another and perpendicular to the hollow chamber wall surface (e.g. aligned parallel to the heat flow direction from the heat source).

### FIELD

The present disclosure relates to the art of heat transfer devices and, in particular, to an expanded graphite-enabled vapor chamber or heat pipe for heat spreading.

### BACKGROUND

Advanced thermal management materials are becoming more and more critical for today's microelectronic, photonic, and photovoltaic systems. As new and more powerful chip designs and light-emitting diode (LED) systems are introduced, they consume more power and generate more heat. This has made thermal management a crucial issue in today's high performance systems. Systems ranging from active electronically scanned radar arrays, web servers, large battery packs for personal consumer electronics, wide-screen displays, and solid-state lighting devices all require high thermal conductivity materials that can dissipate heat more efficiently. Furthermore, many microelectronic devices (e.g. smart phones, flat-screen TVs, tablets, and laptop computers) are designed and fabricated to become increasingly smaller, thinner, lighter, and tighter. This further increases the difficulty of thermal dissipation. Actually, thermal management challenges are now widely recognized as the key barriers to industry's ability to provide continued improvements in device and system performance.

Heat sinks are components that facilitate heat dissipation from the surface of a heat source, such as a CPU or battery in a computing device, to a cooler environment, such as ambient air. Typically, heat transfer between a solid surface and the air is the least efficient within the system, and the solid-air interface thus represents the greatest barrier for heat dissipation. A heat sink is designed to enhance the heat transfer efficiency between a heat source and the air mainly through increased heat sink surface area that is in direct contact with the air. This design enables a faster heat dissipation rate and thus lowers the device operating temperatures.

A vapor-based heat transfer apparatus comprises a hollow structure and a working liquid within the hollow structure. A vapor chamber is a closed structure having an empty space inside within which a liquid is provided. Vapor chambers are typically passive, two-phase (liquid-vapor) heat transport loops that are used to spread heat from relatively small, high heat-flux sources to a region of larger area where the heat can be transferred elsewhere at a significantly lower heat-flux.

A standard heat pipe transfers heat along the axis of the pipe and, thus, is well-suited to cooling discrete heat sources. Vapor chambers are suitable for collecting heat from larger-area heat sources and then spreading the heat or conducting the heat to a heat sink for cooling. Vapor chambers are useful for heat spreading in two dimensions, particularly where high powers and heat fluxes are applied to a relatively small evaporator area. During operation of a vapor chamber, the heat transferred from a heat source to the evaporator can vaporize the liquid within the evaporator wick. The vapor can flow throughout the chamber, serving as an isothermal heat spreader. The vapor then condenses on the condenser surfaces, where the heat may be removed by forced convection, natural convection, liquid cooling, etc. (e.g. through a heat sink). The condensed liquid is transported back to the evaporator via capillary forces in the wick.

Materials for vapor-based heat transfer apparatus (e.g. heat pipe or vapor chamber) must be thermally conducting. Typically, a heat pipe or vapor chamber is made from a metal, especially copper or aluminum, due to the ability of metal to readily transfer heat across its entire structure. However, there are several major drawbacks or limitations associated with the use of metallic chambers. One drawback relates to the relatively low thermal conductivity of a metal (<400 W/mK for Cu and 80-200 W/mK for Al alloy). In addition, the use of copper or aluminum heat transfer apparatus can present a problem because of the weight of the metal, particularly when the heating area is significantly smaller than that of the heat sink. For instance, pure copper weighs 8.96 grams per cubic centimeter (g/cm³) and pure aluminum weighs 2.70 g/cm³. In many applications, several vapor chambers or heat pipes need to be arrayed on a circuit board to dissipate heat from a variety of components on the board. If metallic pipes or chambers are employed, the sheer weight of the metal on the board can increase the chances of the board cracking or of other undesirable effects, and increases the weight of the component itself. Many metals do not exhibit a high surface thermal emissivity and thus do not effectively dissipate heat through the radiation mechanism.

Thus, there is a strong need for a heat pipe or vapor chamber that contains a reduced amount of metal and is effective for dissipating heat produced by a heat source such as a CPU and battery in a device. The heat transfer system should exhibit a higher thermal conductivity and/or a higher thermal conductivity-to-weight ratio as compared to metallic heat sinks. These heat transfer apparatus must also be mass-producible, preferably using a cost-effective process.

### SUMMARY

The present disclosure provides a vapor-based heat transfer apparatus (e.g. a heat pipe or a vapor chamber), comprising (a) a hollow structure made of a thermally conductive material having a thermal conductivity no less than 5 W/mK, more preferably no less than 10 and further more preferably no less than 20 W/mK (e.g. most preferably greater than 50 W/mK or even >100 W/mK, such as Cu, Al, etc.), (b) a wick structure in contact with one or a plurality of walls of the hollow structure, and (c) a working liquid within the hollow structure and in contact with the wick structure, wherein the wick structure comprises flakes of exfoliated graphite worms or expanded graphite.

In certain preferred embodiments, a plurality of walls of the hollow structure comprise an evaporator wall having a first surface plane, and a condenser wall, having a second surface plane wherein the flakes of exfoliated graphite worms or expanded graphite are aligned to be substantially parallel to one another and perpendicular to at least one of the first surface plane and the second surface plane.

In some embodiments, the flakes of exfoliated graphite worms or expanded graphite comprise flakes that are bonded together or bonded to the one or a plurality of hollow structure walls by a binder or adhesive. In some embodiments, the flakes of exfoliated graphite worms or expanded graphite comprise a composite having flakes of exfoliated graphite worms or expanded graphite dispersed in a matrix selected from a polymer, carbon, glass, ceramic, organic, or metal.

In some embodiments, the flakes of exfoliated graphite worms or expanded graphite comprise a coating or paint comprising flakes of exfoliated graphite worms or expanded graphite dispersed in an adhesive and the adhesive is bonded to the interior or exterior surface (or both) of one or a plurality of hollow structure walls.

In some preferred embodiments, the flakes of exfoliated graphite worms or expanded graphite comprise a layer of expanded/exfoliated graphite foam having pores and pore walls containing flakes of exfoliated graphite worms or expanded graphite and the foam has a physical density from 0.001 to 1.8 g/cm³. In some embodiments, the flakes of exfoliated graphite worms or expanded graphite comprise a layer of paper, film, mat, or membrane of flakes of exfoliated graphite worms or expanded graphite.

In some preferred embodiments, the flakes of exfoliated graphite worms or expanded graphite comprise expanded/exfoliated graphite flake-coated metal particles, ceramic particles, carbon particles, glass particles, polymer particles, metal-decorated expanded/exfoliated graphite flakes, ceramic-decorated expanded/exfoliated graphite flakes, or a combination thereof.

The working fluid may contain a fluid selected from water, methyl alcohol, acetone, propylene glycol, refrigerant, ammonia, or alkali metal selected from cesium, potassium or sodium.

Preferably, the thermally conductive material used to construct the hollow structure has a thermal conductivity no less than 100 W/mK. In some embodiments, the thermally conductive material contains a material selected from Cu, Al, steel, Ag, Au, Sn, W, Zn, Ti, Ni, Pb, solder, boron nitride, boron arsenide, diamond, gallium arsenide, aluminum nitride, silicon nitride, or a combination thereof.

The apparatus may further comprise one or more extended structures configured to dissipate heat from the apparatus to an ambient environment, wherein the extended structure has a finned heat sink structure. The apparatus may be physically connected to a heat sink or a cooling system.

In some embodiments, the thermally conductive material that constitutes the hollow structure contains flakes of exfoliated graphite worms or expanded graphite. In some embodiments, the flakes of exfoliated graphite worms or expanded graphite comprise a composite having flakes of exfoliated graphite worms or expanded graphite dispersed in a matrix selected from polymer, carbon, glass, ceramic, organic, or metal.

The disclosure also provides a vapor-based heat transfer apparatus, comprising (a) a hollow structure made of a thermally conductive material, comprising flakes of exfoliated graphite worms or expanded graphite and having a thermal conductivity no less than 5 W/mK, (b) a wick structure in contact with one or a plurality of walls of said hollow structure, and (c) a working liquid within said hollow structure and in contact with said wick structure.

In this apparatus, the thermally conductive graphene material of the hollow structure and/or the wick structure comprises flakes of exfoliated graphite worms or expanded graphite.

In some preferred embodiments, the thermally conductive material that constitutes the hollow structure comprises flakes of exfoliated graphite worms or expanded graphite in a form of a paper, film, membrane, coating, or a composite having flakes of exfoliated graphite worms or expanded graphite dispersed in a matrix selected from polymer, carbon, glass, ceramic, organic, or metal. The metal matrix is preferably selected from Cu, Al, steel, Ag, Au, Sn, W, Zn, Ti, Ni, Pb, solder, or a combination thereof. The ceramic matrix is preferably selected from boron nitride, boron arsenide, diamond, gallium arsenide, aluminum nitride, silicon nitride, or a combination thereof.

The apparatus may further comprise an adhesive that hermetically seals the expanded/exfoliated graphite flake-based paper, film, membrane, or composite.

The disclosure also provides a microelectronic, photonic, or photovoltaic system containing the invented vapor-based heat transfer apparatus as a heat dissipating device.

Also provided is a process for producing the wick structure in the invented heat transfer apparatus, the process comprising: (a) preparing a graphite flake dispersion having multiple flakes of exfoliated graphite worms or expanded graphite dispersed in a liquid; (b) subjecting the graphite flake dispersion to a forced assembly procedure, forcing the multiple graphite flakes to assemble into a liquid-impregnated laminar graphite structure, wherein the multiple graphite flakes are alternately spaced by thin layers of said liquid (preferably less than 10 nm in thickness); and (c) removing the liquid or solidifying the liquid to become a solid wick structure, wherein the flakes of exfoliated graphite worms or expanded graphite in the wick structure are aligned to be substantially parallel to one another and perpendicular to at least one of the first surface plane and the second surface plane.

In certain embodiments, the step of solidifying the liquid comprises polymerizing and/or curing a reactive monomer or resin to form a polymer or a cured resin solid, or cooling the liquid to below a melting point to form a solid.

The disclosure also provides a process for producing a hollow structure element in the invented heat transfer apparatus, the process comprising: (a) preparing a graphite flake dispersion having multiple flakes of exfoliated graphite worms or expanded graphite dispersed in a liquid; (b) subjecting the graphite flake dispersion to a forced assembly procedure, forcing the multiple graphite flakes to assemble into a liquid-impregnated laminar graphite structure, wherein the multiple graphite flakes are alternately spaced by thin layers of the liquid (preferably less than 10 nm in thickness); and (c) removing the liquid or solidifying the liquid to become a solid hollow structure element, wherein the flakes of exfoliated graphite worms or expanded graphite in the hollow structure element are aligned to be substantially parallel to one another and parallel or perpendicular to a surface plane of the hollow structure element. In some embodiments, the step of solidifying the liquid comprises polymerizing and/or curing a reactive monomer or resin to form a polymer or a cured resin solid, or cooling the liquid to below a melting point to form a solid.

### BRIEF DESCRIPTION OF THE DRAWINGS

FIG. 1(A) A flow chart illustrating various prior art processes of producing exfoliated graphite products (graphite worms, flexible graphite foils and expanded graphite flakes), along with a process for producing graphene foam 40a or graphene oxide foams 40b;

FIG. 1(B) Schematic drawing illustrating the processes for producing conventional paper, mat, film, and membrane of simply aggregated graphite flakes or graphene platelets (NGPs). All processes begin with intercalation and/or oxidation treatment of graphitic materials (e.g. natural graphite particles).

FIG. 2(A) Schematic of a vapor chamber having a wick structure comprising flakes of expanded graphite or exfoliated graphite.

FIG. 2(B) Preferred orientation (alignment) direction for the flakes of expanded graphite or exfoliated graphite in the evaporator zone or condenser zone of the wick structure.

FIG. 3(A) Schematic drawing to illustrate an example of a compressing and consolidating operation (using a mold cavity cell equipped with a piston or ram) for forming a layer of highly compacted and oriented graphite flakes. Flakes of graphite worms or expanded graphite are aligned parallel to the bottom plane or perpendicular to the layer thickness direction.

FIG. 3(B) Schematic drawing to illustrate another example of a compressing and consolidating operation (using a mold cavity cell equipped with a piston or ram) for forming a layer of highly compacted and oriented graphite flakes. Graphite flakes are aligned perpendicular to the side plane (X-Y plane) or parallel to the layer thickness direction (Z direction).

FIG. 3(C) Schematic drawing to illustrate yet another example of a compressing and consolidating operation (using a mold cavity cell with a vacuum-assisted suction provision) for forming a layer of highly compacted and oriented graphite flakes. Graphite flakes are aligned parallel to the bottom plane or perpendicular to the layer thickness direction. Preferably, the resulting layer of liquid-impregnated laminar graphite flake structure is further compressed to achieve an even high tap density.

FIG. 3(D) A roll-to-roll process for producing a thick layer of liquid-impregnated laminar graphite structure. Graphite flakes are well-aligned on the supporting substrate plane.

FIG. 4 An example of vapor chamber/heat pipe production processes.

### DETAILED DESCRIPTION OF PREFERRED EMBODIMENTS

The present disclosure provides a vapor-based heat transfer apparatus (e.g. a heat pipe or a vapor chamber, as schematically shown in FIG. 2), comprising (a) a hollow structure (or hollow chamber) comprising a thermally conductive material having a thermal conductivity preferably no less than 5 W/mK and further preferably no less than 10 W/mK (e.g. Cu, Al, etc.), (b) a wick structure in contact with one or a plurality of walls of the hollow structure, and (c) a working liquid within the hollow structure and in contact with the wick structure, wherein the wick structure comprises flakes of exfoliated graphite worms or expanded graphite.

In certain preferred embodiments, as illustrated in FIG. 2(B), the flakes of expanded graphite or exfoliated graphite in the evaporator zone or condenser zone of the wick structure are preferentially aligned parallel to X-Z plane directions. These graphite flakes are substantially parallel to one another and perpendicular to the surface plane of the evaporator portion of the chamber wall (or perpendicular to the surface plane of the wick structure). Such an orientation of flakes enables faster heat transfer from the heat source to the evaporator region and faster transport of condensed liquid returning back to the evaporator zone of the wick structure via capillary forces.

The heat coming from a heat source (below the hollow structure in FIG. 2(A)) is conducted through the lower portion (evaporator portion) of the hollow structure to vaporize the working fluid in or near the wick structure, (in what may be called evaporative surfaces of the wick structure near the heat source). The vapor may quickly fill the chamber of the hollow structure, serving as an isothermal heat spreader; some of the vapor comes in contact with the upper portion (condenser portion) of the hollow structure and get condensed on the wick structure, (in what may be called condenser surfaces of the wick structure near the heat sink. The condensed fluid (e.g. water) flows back to the lower portion (hotter portion) through the wick structure via capillary forces in the wick. The returned liquid continues to get vaporized provided the heat source continues to pump heat into the chamber. It should be understood that the heat source may include any type of heat source, including such examples as a controller/processor or any type of integrated circuit, any type of electronics, microelectronic system, photonic system, photovoltaic system, or anything else for which it is desirable to remove heat therefrom.

A first type of wick structure may contain a sintered body of particles (e.g. flakes of exfoliated graphite worms or expanded graphite or graphite flake-coated Cu particles) having some surface pores or internal pores. This type of wick structure offers the highest degree of versatility in terms of power handling capacity and ability to work against gravity. A second type of wick structure may contain a mesh screen, which is less expensive to manufacture and allows the heat pipe or vapor chamber to be thinner relative to a sintered wick. However, due to the capillary force of the screen being significantly less than that of a sintered wick, its ability to work against gravity or handle higher heat loads is lower. The third type of a wick structure is a grooved wick whose cost and performance is the lowest of the three. The grooves may act as an internal fin structure aiding in the evaporation and condensation.

In addition to or alternatively, the thermally conductive material used in the hollow structure may also comprise flakes of exfoliated graphite worms or expanded graphite. In the presently invented vapor-based heat transfer apparatus, either the wick structure or the hollow structure (or both) may comprise flakes of exfoliated graphite worms or expanded graphite.

In some embodiments, the flakes of exfoliated graphite worms or expanded graphite may be in a form of paper, film, membrane, coating/paint, or a composite having flakes of exfoliated graphite worms or expanded graphite dispersed in a matrix selected from polymer, carbon, glass, ceramic, organic, or metal.

The production of flakes of exfoliated graphite worms or expanded graphite, graphite flake-reinforced composites, paper, film membrane, or foam of flakes of exfoliated graphite worms or expanded graphite, each as a material, will be briefly described as follows:

Exfoliated graphite may be obtained by immersing powders or filaments of a starting graphitic material (e.g. natural graphite powder) in an oxidizing liquid medium (e.g. a mixture of sulfuric acid, nitric acid, and potassium permanganate) in a reaction vessel at a desired temperature for a period of time (typically from 0.5 to 96 hours, depending upon the nature of the starting material and the type of oxidizing agent used). The resulting graphite oxide particles (sulfuric acid-intercalated graphite or graphite intercalation compound, GIC) may then be subjected to thermal exfoliation to produce exfoliated graphite worms. Graphite worms are composed of exfoliated graphite flakes that remain weakly interconnected. Graphite worms may be broken up by using mechanical shearing, air jet milling, ultrasonication, etc.

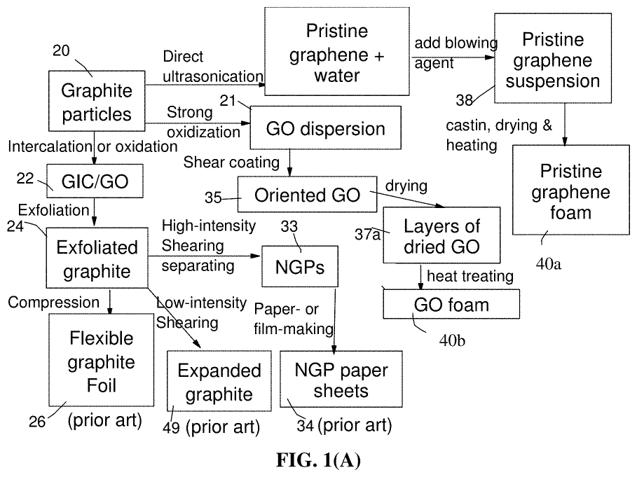

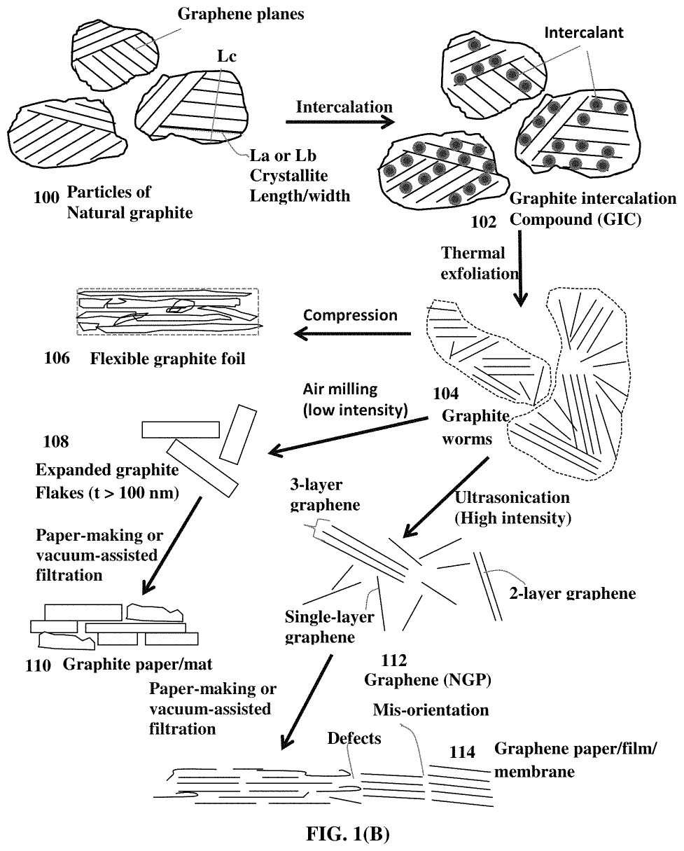

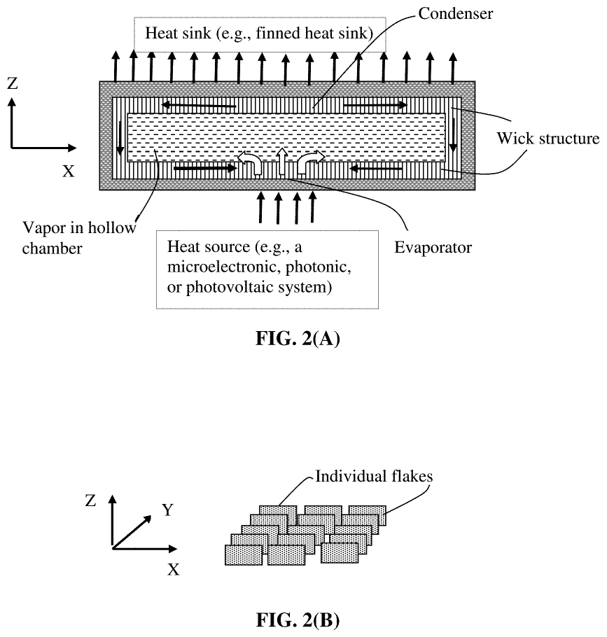

The aforementioned features are further described and explained in detail as follows: As illustrated in FIG. 1(B), a graphite particle (e.g. 100) is typically composed of multiple graphite crystallites or grains. A graphite crystallite is made up of layer planes of hexagonal networks of carbon atoms. These layer planes of hexagonally arranged carbon atoms are substantially flat and are oriented or ordered so as to be substantially parallel and equidistant to one another in a particular crystallite. These layers of hexagonal-structured carbon atoms, commonly referred to as graphene layers or basal planes, are weakly bonded together in their thickness direction (crystallographic c-axis direction) by weak van der Waals forces and groups of these graphene layers are arranged in crystallites. The graphite crystallite structure is usually characterized in terms of two axes or directions: the c-axis direction and the a-axis (or b-axis) direction. The c-axis is the direction perpendicular to the basal planes. The a- or b-axes are the directions parallel to the basal planes (perpendicular to the c-axis direction).

A highly ordered graphite particle can consist of crystallites of a considerable size, having a length of Lₐ along the crystallographic a-axis direction, a width of L_{b} along the crystallographic b-axis direction, and a thickness L_{c} along the crystallographic c-axis direction. The constituent graphene planes of a crystallite are highly aligned or oriented with respect to each other and, hence, these anisotropic structures give rise to many properties that are highly directional. For instance, the thermal and electrical conductivity of a crystallite are of great magnitude along the plane directions (a- or b-axis directions), but relatively low in the perpendicular direction (c-axis). As illustrated in the upper-left portion of FIG. 1(B), different crystallites in a graphite particle are typically oriented in different directions and, hence, a particular property of a multi-crystallite graphite particle is the directional average value of all the constituent crystallites.

Due to the weak van der Waals forces holding the parallel graphene layers, natural graphite can be treated so that the spacing between the graphene layers can be appreciably opened up so as to provide a marked expansion in the c-axis direction, and thus form an expanded graphite structure in which the laminar character of the carbon layers is substantially retained. The process for manufacturing flexible graphite is well-known in the art. In general, flakes of natural graphite (e.g. 100 in FIG. 1(B)) are intercalated in an acid solution to produce graphite intercalation compounds (GICs, 102). The GICs are washed, dried, and then exfoliated by exposure to a high temperature for a short period of time. This causes the flakes to expand or exfoliate in the c-axis direction of the graphite up to 80-300 times of their original dimensions. The exfoliated graphite flakes are vermiform in appearance and, hence, are commonly referred to as graphite worms 104.

These worms of graphite flakes which have been greatly expanded can be formed without the use of a binder into cohesive or integrated sheets of expanded graphite, e.g. webs, papers, strips, tapes, foils, mats or the like (typically referred to as “flexible graphite” 106) having a typical density of about 0.04-2.0 g/cm³ for most applications.

The upper left portion of FIG. 1(A) shows a flow chart that illustrates the prior art processes used to fabricate flexible graphite foils. The processes typically begin with intercalating graphite particles 20 (e.g., natural graphite or synthetic graphite) with an intercalant (typically a strong acid or acid mixture) to obtain a graphite intercalation compound 22 (GIC). After rinsing in water to remove excess acid, the GIC becomes “expandable graphite.” The GIC or expandable graphite is then exposed to a high temperature environment (e.g., in a tube furnace preset at a temperature in the range from 800-1,050° C.) for a short duration of time (typically from 15 seconds to 2 minutes). This thermal treatment allows the graphite to expand in its c-axis direction by a factor of 30 to several hundreds to obtain a worm-like vermicular structure 24 (graphite worm), which contains exfoliated, but un-separated graphite flakes with large pores interposed between these interconnected flakes.

The exfoliated graphite (or mass of graphite worms) may be re-compressed by using a calendaring or roll-pressing technique to obtain flexible graphite foils (26 in FIG. 1(A) or 106 in FIG. 1(B)), which are typically 100-300 μm thick. In another process, the exfoliated graphite worm 24 may be impregnated with a resin and then compressed and cured to form a flexible graphite composite.

Alternatively, the exfoliated graphite may be subjected to high-intensity mechanical shearing/separation treatments using a high-intensity air jet mill, high-intensity ball mill, or ultrasonic device to produce separated nanographene platelets 33 (NGPs) with all the graphene platelets thinner than 100 nm, mostly thinner than 10 nm, and, in many cases, being single-layer graphene (also illustrated as 112 in FIG. 1(B)). An NGP is composed of a graphene sheet or a plurality of graphene sheets with each sheet being a two-dimensional, hexagonal structure of carbon atoms. A mass of multiple NGPs (including discrete sheets/platelets of single-layer and/or few-layer graphene or graphene oxide, 33 in FIG. 1(A)) may be made into a graphene film/paper (34 in FIG. 1(A) or 114 in FIG. 1(B)) using a film- or paper-making process.

Further alternatively, with a low-intensity shearing, graphite worms tend to be separated into the so-called expanded graphite flakes (108 in FIG. 1(B) having a thickness >100 nm. These flakes can be formed into graphite paper or mat 106 using a paper- or mat-making process. This expanded graphite paper or mat 106 is just a simple aggregate or stack of discrete flakes that could have defects, interruptions, and mis-orientations between these discrete flakes.

The present disclosure provides a process for producing a highly oriented (aligned), adhesive-impregnated laminar graphite flake structure for use as a wick electrode or as a vapor chamber/heat pipe hollow structure. This adhesive may be initially in a liquid state (e.g. uncured resin, metal melt, pitch, etc.), but becomes solidified after the wick structure or hollow structure element is made. In some embodiments, the process comprises: (a) preparing a graphite flake dispersion having multiple flakes of exfoliated graphite worms or expanded graphite dispersed in (or impregnated with) a liquid; (b) subjecting the graphite flake dispersion to a forced assembly procedure, forcing the multiple graphite flakes to assemble into the liquid-impregnated laminar graphite structure, wherein the multiple graphite flakes are alternately spaced by thin liquid layers, less than 10 nm (preferably <5 nm) in thickness, and the multiple graphite flakes are substantially aligned along a desired direction, and wherein the laminar graphite flake structure has a physical density from 0.5 to 1.6 g/cm³ (more typically 0.7-1.3 g/cm³) and a specific surface area from 50 to 3,300 m²/g, when measured in a dried state of the laminar structure without the presence of the liquid; and (c) removing/drying the liquid or solidifying the liquid to become a solid (e.g. polymerizing and/or curing a reactive monomer or resin to form a polymer or cured resin solid; or cooling the liquid to below the melting point for solidification).

In some desired embodiments, the forced assembly procedure includes introducing a graphite flake dispersion, having an initial volume V₁, in a mold cavity cell and driving a piston into the mold cavity cell to reduce the graphite flake dispersion volume to a smaller value V₂, allowing excess liquid to flow out of the cavity cell (e.g. through holes of the mold cavity cell or of the piston) and aligning the multiple graphite flakes along a direction at an angle from 0° to 90° relative to a movement direction of the piston. The liquid may be intended to be an adhesive or simply a fluid medium to facilitate the flow of graphite flakes.

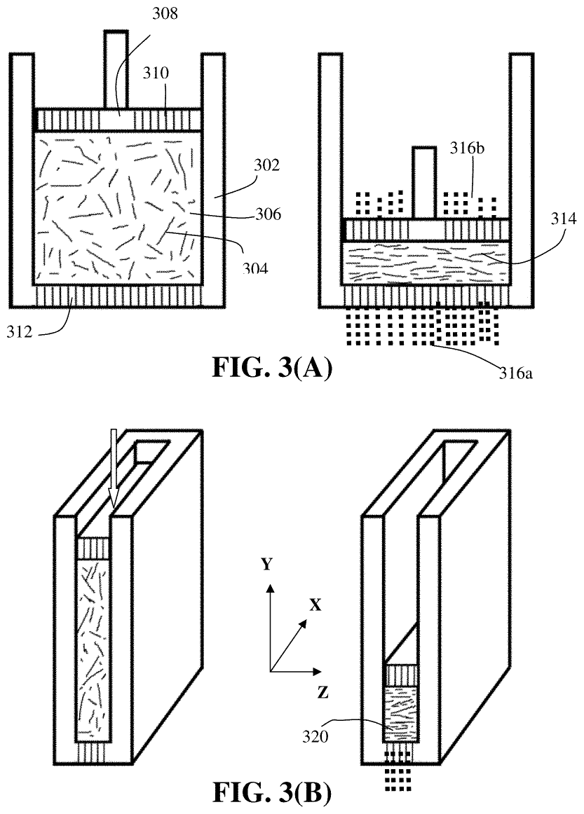

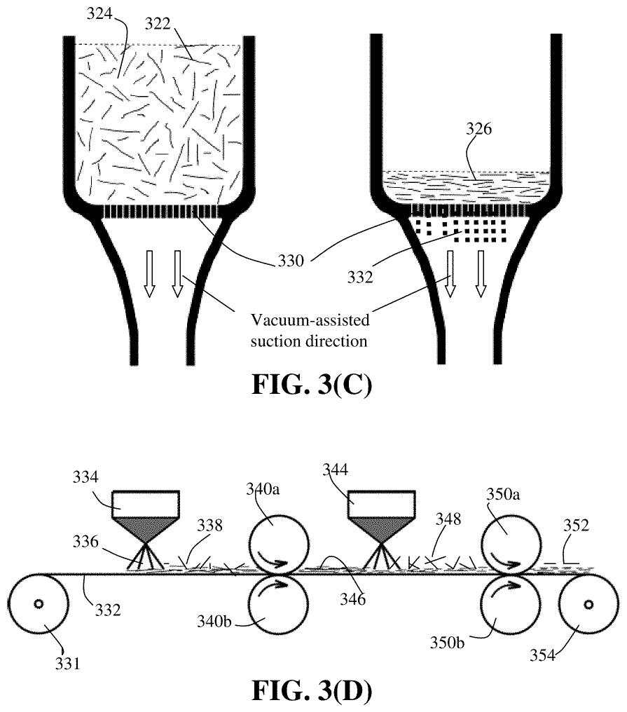

FIG. 3(A) provides a schematic drawing to illustrate an example of a compressing and consolidating operation (using a mold cavity cell 302 equipped with a piston or ram 308) for forming a layer of highly compacted and oriented graphite flakes 314. Contained in the chamber (mold cavity cell 302) is a dispersion (e.g. suspension or slurry that is composed of expanded graphite flakes 304 randomly dispersed in a liquid 306). As the piston 308 is driven downward, the volume of the dispersion is decreased by forcing excess liquid to flow through minute channels 312 on a mold wall or through small channels 310 of the piston. These small channels can be present in any or all walls of the mold cavity and the channel sizes can be designed to permit permeation of the liquid, but not the solid graphite flakes (typically 0.5-10 μm in length or width). The excess liquid is shown as 316a and 316b on the right diagram of FIG. 3(A). As a result of this compressing and consolidating operation, graphite flakes 314 are aligned parallel to the bottom plane or perpendicular to the layer thickness direction.

In this dispersion, if so desired, practically each and every isolated graphite flake is surrounded by the liquid (e.g. adhesive) that is physically adsorbed on or chemically bonded to graphite flake surface. During the subsequent consolidating and aligning operation, isolated graphite flakes remain isolated or separated from one another through liquid (e.g. adhesive). Upon removal of the excess liquid, graphite flakes remain spaced apart by liquid adhesive and this liquid adhesive-filled space can be as small as 0.4 nm.

Shown in FIG. 3(B) is a schematic drawing to illustrate another example of a compressing and consolidating operation (using a mold cavity cell equipped with a piston or ram) for forming a layer of highly compacted and oriented graphite flakes 320. The piston is driven downward along the Y-direction. The graphite flakes are aligned on the X-Z plane and perpendicular to X-Y plane (along the Z- or thickness direction). This layer of oriented graphite flakes, as a wick structure, can be attached to a hollow structure interior surface that is basically represented by the X-Y plane. In the resulting hollow chamber structure, graphite flakes (e.g. in an evaporator portion) are aligned perpendicular to the evaporator plane. Such an orientation is conducive to a faster heat transfer from a heat source to the evaporator portion of the wick structure and, hence, leads to a faster vaporization of the working fluid as compared to the corresponding evaporator structure featuring graphite flakes being aligned parallel to the evaporator plane.

FIG. 3(C) provides a schematic drawing to illustrate yet another example of a compressing and consolidating operation (using a mold cavity cell with a vacuum-assisted suction provision) for forming a layer of highly compacted and oriented graphite flakes 326. The process begins with dispersing isolated graphite flakes 322 and an optional filler in a liquid 324 to form a dispersion. This is followed by generating a negative pressure via a vacuum system that sucks excess liquid 332 through channels 330. This compressing and consolidating operation acts to reduce the dispersion volume and align all the isolated graphite flakes on the bottom plane of a mold cavity cell. Compacted graphite flakes are aligned parallel to the bottom plane or perpendicular to the layer thickness direction. Preferably, the resulting layer laminar graphite flake structure is further compressed to achieve an even high tap density.

Thus, in some desired embodiments, the forced assembly procedure includes introducing dispersion of graphite flakes in a mold cavity cell having an initial volume V₁, and applying a suction pressure through a porous wall of the mold cavity to reduce the graphite dispersion volume to a smaller value V₂, allowing excess liquid to flow out of the cavity cell through the porous wall and aligning the multiple graphite flakes along a direction at an angle from approximately 0° to approximately 90° relative to a suction pressure direction; this angle depending upon the inclination of the bottom plane with respect to the suction direction.

FIG. 3(D) shows a roll-to-roll process for producing a thick layer of adhesive-impregnated (or un-impregnated) laminar graphite flake structure. This process begins by feeding a continuous solid substrate 332 (e.g. PET film or stainless steel sheet) from a feeder roller 331. A dispenser 334 is operated to dispense dispersion 336 of isolated graphite flakes and liquid onto the substrate surface to form a layer of deposited dispersion 338, which feeds through the gap between two compressing rollers, 340a and 340b, to form a layer of liquid-impregnated, highly oriented graphite flakes. The graphite flakes are well-aligned on the supporting substrate plane. If so desired, a second dispenser 344 is then operated to dispense another layer of dispersion 348 on the surface of the previously consolidated dispersion layer. The two-layer structure is then driven to pass through the gap between two roll-pressing rollers 350a and 350b to form a thicker layer 352 of liquid-impregnated laminar graphite flake structure, which is taken up by a winding roller 354. In certain embodiments, the liquid is removed; but in other the liquid (e.g. adhesive) stays in the spaces between expanded graphite flakes.

Thus, in some preferred embodiments, the forced assembly procedure includes introducing a first layer of the graphite flake dispersion onto a surface of a supporting conveyor and driving the layer of graphite flake suspension supported on the conveyor through at least a pair of pressing rollers to reduce the thickness of the graphite dispersion layer and align the multiple graphite flakes along a direction parallel to the conveyor surface for forming a layer of liquid-impregnated laminar graphite structure.

The process may further include a step of introducing a second layer of the graphite dispersion onto a surface of the layer of liquid-impregnated laminar structure to form a two layer laminar structure, and driving the two-layer laminar structure through at least a pair of pressing rollers to reduce a thickness of the second layer of graphite flake dispersion and align the multiple graphite flakes along a direction parallel to the conveyor surface for forming a layer of liquid-impregnated laminar structure. The same procedure may be repeated by allowing the conveyor to move toward a third set of pressing rollers, depositing additional (third) layer of graphite flake dispersion onto the two-layer structure, and forcing the resulting 3-layer structure to go through the gap between the two rollers in the third set to form a further compacted, liquid-impregnated laminar graphite flake structure.

The above paragraphs about FIG. 3(A)-FIG. 3(D) are but four of the many examples of possibly apparatus or processes that can be used to produce liquid-impregnated laminar graphite flake strictures that contain highly oriented and closely packed graphite flakes spaced by thin layers of liquid. This liquid may be removed/dried during any stage of compressing or consolidating. The liquid (if containing an adhesive, for instance) may be allowed to stay in the spaces between graphite flakes.

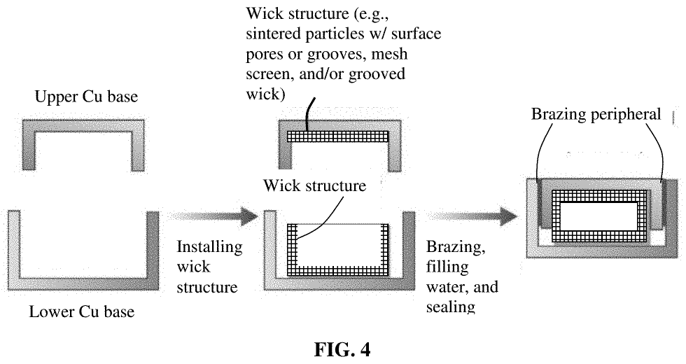

There are many feasible ways of producing the invented vapor-based heat transfer device. For instance, as schematically illustrated in FIG. 4, one may prepare two members of a hollow structure (e.g. an upper Cu base and a lower Cu base), install the two mating portions of an expanded/exfoliated graphite-based wick structure, fit and braze the two members together, fill the working fluid (e.g. water), and seal the gaps to form the desired vapor chamber. The two upper and lower bases may be produced from a graphene- or graphite-reinforced Cu/Sn alloy or polymer using injection molding or compression molding. The wick structures may contain a layer of film, foam, paper, or membrane of flakes of exfoliated graphite worms or expanded graphite, compacted graphite-coated Cu particles, etc. There can be supporting spacers between the upper and the lower members of the hollow structure.

A first type of wick structure may contain a sintered body of particles having some surface pores or grooves. This type of wick structure offers the highest degree of versatility in terms of power handling capacity and ability to work against gravity. A second type of wick structure may contain a mesh screen, which is less expensive to manufacture and allows the heat pipe or vapor chamber to be thinner relative to a sintered wick. However, due to the capillary force of the screen being significantly less than a sintered wick, its ability to work against gravity or handle higher heat loads is lower. The third type of a wick structure is a grooved wick whose cost and performance is the lowest of the three. The grooves may act as an internal fin structure aiding in the evaporation and condensation. Any suitable wick structure could be used. Further, a graphene-filled adhesive can be employed, and may be used in a coating or paint.

During operation of a vapor chamber, the heat transferred from a heat source to the evaporator can vaporize the liquid within the evaporator wick. The presence of a graphite flake-based chamber wall structure and/or graphite flake-based wick structure enables significantly faster heat transfer from the heat source to the evaporator portion of the wick structure, allowing for more efficient evaporation of the working fluid. The vapor can flow throughout the chamber, serving as an isothermal heat spreader. The vapor then condenses on the condenser surfaces, where the heat may be removed by forced convection, natural convection, liquid cooling, etc.

[e.g. through a heat sink (such as is shown in FIG. 2(A), which may include an extended structure such as a finned heat sink)]. The condensed liquid is transported back to the evaporator via capillary forces in the wick. The expanded/exfoliated graphite flakes can be chemically treated to make graphene surfaces favorable or conducive to wetting and movement of the condensed working fluid.

We have observed that the presently invented expanded/exfoliated graphite flake-based wick structure enables a vapor chamber to deliver 1.5-3.5 times higher maximum heat flux in comparison with a vapor chamber of the same dimensions but featuring a conventional Cu-based wick structure. For instance, one can easily achieve a maximum heat flux of >>1,500 W/cm² (over an area of 4 cm²) for a vapor chamber having an optimized graphite flake-based wick. The heat flux value is even significantly higher if a graphite flake-reinforced Cu hollow chamber wall is implemented. Any microelectronic, photonic, or photovoltaic system may be made to contain the invented vapor-based heat transfer apparatus as a heat dissipating device to help keep the system cool.

The following examples serve to provide the best modes of practice for the presently disclosed process and should not be construed as limiting the scope of the process:

### Example 1: Preparation of Wick Structures and Hollow Structures Based on Exfoliated Graphite Worms and Expanded Graphite Flakes from Meso-Carbon Micro-Beads (MCMBs)

Meso-carbon microbeads (MCMBs) were supplied from China Steel Chemical Co., Kaohsiung, Taiwan. This material has a density of about 2.24 g/cm³ with a median particle size of about 16 μm. MCMB (10 grams) were intercalated with an acid solution (sulfuric acid, nitric acid, and potassium permanganate at a ratio of 4:1:0.05) for a period of time from 4 hours up to 48 hours. Upon completion of the reaction, the mixture was poured into deionized water and filtered. The intercalated MCMBs were repeatedly washed in a 5% solution of HCl to remove most of the sulfate ions. The sample was then washed repeatedly with deionized water until the pH of the filtrate was no less than 4.0. The slurry was then dried in a vacuum for 24 hours to obtain a graphite intercalation compound (GIC).

The GIC was then thermally exfoliated at 650° C. for 1 minute to produce exfoliated graphite worms, which were divided into two portions. One portion was subjected to chemical activation by mixing the graphite worms with KOH at a 1:1 weight ratio and then heated the mixture to 800° C. for 2 hours to produce activated graphite worms, having a specific surface area of 1,770 m²/g. The other portion, having a specific surface area of 341 m²/g, was used as a control sample. The activated graphite worms having a high specific surface area, when used as a wick structure, behave like a piece of sponge, being significantly more capable of transporting condensed liquid from the condenser region back to the evaporator region via capillary forces.

The graphite worms, with or without chemical activation, were then made into wick structures using both the presently invented processes (wick structure containing oriented expanded graphite flakes, perpendicular to the evaporator plane; prepared according to a procedure as illustrated in FIG. 3(C)) and the conventional production process (flexible graphite sheets and composites of resin-bonded expanded graphite sheets). Resin-bonded/sealed expanded graphite flakes were also used in a hollow chamber structure in a vapor chamber device. Cu based wick and hollow structures were also prepared for comparison purposes.

### Example 2: Preparation of Wick Structures Based on Exfoliated Graphite Worms and Expanded Graphite Flakes from Short Graphite Fibers

Chopped graphite fibers with an average diameter of 12 μm and natural graphite particles were separately used as a starting material, which was immersed in a mixture of concentrated sulfuric acid, nitric acid, and potassium permanganate (as the chemical intercalate and oxidizer) to prepare graphite intercalation compounds (GICs). The starting material was first dried in a vacuum oven for 24 h at 80° C. Then, a mixture of concentrated sulfuric acid, fuming nitric acid, and potassium permanganate (at a weight ratio of 4:1:0.05) was slowly added, under appropriate cooling and stirring, to a three-neck flask containing fiber segments. After 4 hours of reaction, the acid-treated graphite fibers or natural graphite particles were filtered and washed thoroughly with deionized water until the pH level of the solution reached 6. After drying the product at 100° C. overnight, we obtained a graphite intercalation compound (GIC) or graphite oxide fiber.

The GIC was then submitted to a thermal exfoliation treatment at 800° C. for 45 seconds to obtain exfoliated graphite worms. Some of these worms were submitted to low-intensity shearing using a kitchen-scale food processor to produce expanded graphite flakes.

A portion of the expanded graphite flakes was dispersed in a UV-curable liquid adhesive to form a dispersion. Part of the dispersion was compressed and consolidated into a layer of adhesive-impregnated, compacted and highly oriented graphite flakes (adhesive-impregnated laminar graphite flake structure) according to the process illustrated in FIG. 3(A). This was bonded to an evaporator portion and a condenser portion of a Cu-based hollow chamber with the graphite flakes aligned parallel to the evaporator plane. Other part of the dispersion was made into a layer of adhesive-impregnated laminar structure having graphite flakes aligned perpendicular to the evaporator plane, according to a procedure as illustrated in FIG. 3(B). The adhesive was subsequently cured after the respective wick structures (with a parallel or a perpendicular orientation) were attached to the interior wall surfaces of a vapor chamber.

### Example 3: Preparation of Exfoliated Graphite Worms and Wick Structures from Natural Graphite

Graphite intercalation compound or graphite oxide was prepared by oxidation of natural flake graphite with an oxidizer liquid consisting of sulfuric acid, sodium nitrate, and potassium permanganate at a ratio of 4:1:0.05 at 30° C. When natural graphite flakes (particle sizes of 25 μm) were immersed and dispersed in the oxidizer mixture liquid for 4 hours, the suspension or slurry remains optically opaque and dark. After this, the reacting mass was rinsed with water 3 times to adjust the pH value to at least 3.0. The mass was then dried in a vacuum oven at 80° C. for 24 hours to obtain a GIC. The GIC was thermally exfoliated at 900° C. for 60 seconds to obtain exfoliated graphite worms. Some of the worms were subjected to low-intensity shearing using a food processor to obtain powder of expanded graphite flakes. Some amount of the worms and some amount of the expanded graphite flakes were subjected to chemical activation (using NaOH melt at 800° C. for 6 hours) to obtain activated graphite worms and activated expanded graphite flakes, respectively.

Some of these graphite flakes (activated or non-activated) and some of these graphite worms (activated or non-activated) were then dispersed in water to form several dispersion samples, which were then made into wick structures using the presently invented process (roll-pressing-based as illustrated in FIG. 3(C)). Water was removed during and after roll-pressing. The structures were cut and trimmed to layers having a thickness from 20 μm to 2 mm, which were used as a wick structure in a vapor chamber containing an Al-based hollow chamber wherein an external surface of this hollow chamber was deposited with an expanded graphite/epoxy coating layer using ultrasonic spray coating.

### Example 4: Preparation of Expanded Graphite Flake-Coated Cu Particles for Use as a Wick Structure

Some amount of the dried expanded graphite flake powder prepared in Example 3, along with Cu particles, was poured into a ball-milling pot chamber and then ball-milled in a plenary ball milling device for 30 minutes to obtain expanded graphite-coated Cu particles. Certain amounts of the expanded graphite-coated Cu particles were compacted, using a compression press, to form layers of compacted expanded graphite-coated Cu particles. Some of compacted layers were used as a wick structure in a vapor chamber. Other layers were melted and solidified to make expanded graphite flake-reinforced Cu composite-based hollow structures for vapor chambers and heat pipes.

1. A vapor-based heat transfer apparatus, comprising (a) a hollow structure comprising a thermally conductive material having a thermal conductivity no less than 5 W/mK, (b) a wick structure in contact with one or a plurality of walls of said hollow structure, and (c) a working liquid within said hollow structure and in contact with said wick structure, wherein said wick structure comprises flakes of exfoliated graphite worms or expanded graphite.

2. The apparatus of claim 1, wherein said a plurality of walls of said hollow structure comprise an evaporator wall having a first surface plane, and a condenser wall, having a second surface plane wherein said flakes of exfoliated graphite worms or expanded graphite in said wick structure are aligned to be substantially parallel to one another and perpendicular to at least one of said first surface plane and said second surface plane.

3. The apparatus of claim 1, wherein said flakes of exfoliated graphite worms or expanded graphite are bonded together or bonded to said one or a plurality of hollow structure walls by a binder.

4. The apparatus of claim 2, wherein said flakes of exfoliated graphite worms or expanded graphite are bonded together or bonded to said one or a plurality of hollow structure walls by a binder.

5. The apparatus of claim 1, wherein said flakes of exfoliated graphite worms or expanded graphite are dispersed in or bonded by a matrix material selected from a polymer, carbon, glass, ceramic, organic, or metal.

6. The apparatus of claim 1, wherein said flakes of exfoliated graphite worms or expanded graphite are dispersed in an adhesive to form a coating or paint and said adhesive is bonded to an interior or exterior surface of said one or a plurality of hollow structure walls.

7. The apparatus of claim 1, wherein said flakes of exfoliated graphite worms or expanded graphite form a foam structure having pores and pore walls and said expanded or exfoliated graphite foam has a physical density from 0.001 to 1.8 g/cm³.

8. The apparatus of claim 1, wherein said flakes of exfoliated graphite worms or expanded graphite are in a form of paper, film, mat, or membrane.

9. The apparatus of claim 1, wherein said working fluid contains a fluid selected from water, methyl alcohol, propylene glycol, acetone, refrigerant, ammonia, or alkali metal selected from cesium, potassium or sodium.

10. The apparatus of claim 1, wherein said thermally conductive material has a thermal conductivity no less than 100 W/mK.

11. The apparatus of claim 1, wherein said thermally conductive material contains a material selected from Cu, Al, steel, Ag, Au, Sn, W, Zn, Ti, Ni, Pb, solder, boron nitride, boron arsenide, diamond, gallium arsenide, aluminum nitride, silicon nitride, or a combination thereof.

12. The apparatus of claim 1, wherein said thermally conductive material contains flakes of exfoliated graphite worms or expanded graphite.

13. The apparatus of claim 2, wherein said thermally conductive material contains flakes of exfoliated graphite worms or expanded graphite that are aligned to be substantially parallel to one another and parallel to at least one of said first surface plane and said second surface plane.

14. The apparatus of claim 12, wherein said flakes of exfoliated graphite worms or expanded graphite are dispersed in a matrix selected from polymer, carbon, glass, ceramic, organic, or metal.

15. A vapor-based heat transfer apparatus, comprising (a) a hollow structure made of a thermally conductive material having a thermal conductivity no less than 5 W/mK, (b) a wick structure in contact with one or a plurality of walls of said hollow structure, and (c) a working liquid within said hollow structure and in contact with said wick structure; wherein said thermally conductive material comprises flakes of exfoliated graphite worms or expanded graphite in a form of paper, film, membrane, coating, or a composite having flakes of exfoliated graphite worms or expanded graphite dispersed in a matrix selected from carbon, glass, ceramic, organic, or metal.

16. The apparatus of claim 15, further comprising an adhesive that hermetically seals said paper, graphene film, membrane, or composite.

17. The apparatus of claim 1, further comprising one or more extended structures configured to dissipate heat from said apparatus to an ambient environment.

18. The apparatus of claim 17, wherein said extended structure contains a finned heat sink structure.

19. A microelectronic, photonic, or photovoltaic system containing said apparatus of claim 1 as a heat dissipating device.

20. A process for producing the wick structure in said heat transfer apparatus of claim 2, said process comprising: (a) preparing a graphite flake dispersion having multiple flakes of exfoliated graphite worms or expanded graphite dispersed in a liquid; (b) subjecting the graphite flake dispersion to a forced assembly procedure, forcing the multiple graphite flakes to assemble into a liquid-impregnated laminar graphite structure, wherein the multiple graphite flakes are alternately spaced by thin layers of said liquid, less than 10 nm in thickness; and (c) removing the liquid or solidifying the liquid to become a solid wick structure, wherein said flakes of exfoliated graphite worms or expanded graphite in said wick structure are aligned to be substantially parallel to one another and perpendicular to at least one of said first surface plane and said second surface plane.

21. The process of claim 20, wherein said step of solidifying the liquid comprises polymerizing and/or curing a reactive monomer or resin to form a polymer or a cured resin solid, or cooling the liquid to below a melting point to form a solid.

22. A process for producing a hollow structure element in said heat transfer apparatus of claim 15, said process comprising: (a) preparing a graphite flake dispersion having multiple flakes of exfoliated graphite worms or expanded graphite dispersed in a liquid; (b) subjecting the graphite flake dispersion to a forced assembly procedure, forcing the multiple graphite flakes to assemble into a liquid-impregnated laminar graphite structure, wherein the multiple graphite flakes are alternately spaced by thin layers of said liquid, less than 10 nm in thickness; and (c) removing the liquid or solidifying the liquid to become a solid hollow structure element, wherein said flakes of exfoliated graphite worms or expanded graphite in said hollow structure element are aligned to be substantially parallel to one another and parallel or perpendicular to a surface plane of said hollow structure element.

23. The process of claim 22, wherein said step of solidifying the liquid comprises polymerizing and/or curing a reactive monomer or resin to form a polymer or a cured resin solid, or cooling the liquid to below a melting point to form a solid.

24. The process of claim 20, wherein said forced assembling and orientating procedure includes introducing said graphite flake dispersion, having an initial volume V₁, in a mold cavity cell and driving a piston into said mold cavity cell to reduce the graphite flake dispersion volume to a smaller value V₂, allowing excess liquid to flow out of said cavity cell and aligning said flakes along a desired direction.

25. The process of claim 20, wherein said forced assembling and orientating procedure includes introducing said graphite flake dispersion in a mold cavity cell having an initial volume V₁, and applying a suction pressure through a porous wall of said mold cavity to reduce the graphite flake dispersion volume to a smaller value V₂, allowing excess liquid to flow out of said cavity cell through said porous wall and aligning said flakes along a desired direction.

26. The process of claim 20, wherein said forced assembling and orientating procedure includes introducing a first layer of said graphite flake dispersion onto a surface of a supporting conveyor and driving said layer of graphite flake dispersion supported on said conveyor through at least a pair of pressing rollers to reduce a thickness of said graphite flake dispersion layer and align said flakes along a direction parallel to said conveyor surface for forming a layer of liquid-impregnated flakes.

27. The process of claim 26, further including a step of introducing a second layer of said graphite flake dispersion onto a surface of said layer of liquid-impregnated flakes to form a two-layer structure, and driving said two-layer structure through at least a pair of pressing rollers to reduce a thickness of said second layer of graphite flake dispersion and align said flakes along a direction parallel to said conveyor surface for forming a layer of liquid-impregnated flakes.

28. The process of claim 20, further including a step of compressing or roll-pressing said liquid-impregnated flakes to reduce a thin liquid layer thickness in said impregnated flakes, improve orientation of flakes, and squeeze excess liquid out of said impregnated flakes.

29. The process of claim 28, which is a roll-to-roll process wherein said forced assembling and orientating procedure includes feeding said supporting conveyor, in a continuous film form, from a feeder roller to a deposition zone, continuously or intermittently depositing said graphite flake dispersion onto a surface of said supporting conveyor film to form said layer of liquid-impregnated flakes thereon, and collecting said layer of liquid-impregnated flakes supported on conveyor film on a collector roller.
